(19) United States
(12) Patent Application Publication
(10) Pub. No.: US 2007/0224780 A1
(43) Pub. Date: Sep. 27, 2007

(54) METHOD FOR DICING A WAFER

(75) Inventors: Fu Tang CHU, Fongshan City (TW); Chi Yuam CHUNG, Kaohsiung City (TW)

Correspondence Address: LOWE HAUPTMAN BERNER, LLP, 1700 DIAGONAL ROAD, SUITE 300, ALEXANDRIA, VA, 22314, US

(73) Assignee: ADVANCED SEMICONDUCTOR ENGINEERING INC., KAOHSIUNG (TW)

(21) Appl. No.: 11/466,387

(22) Filed: Aug. 22, 2006

(30) Foreign Application Priority Data
Mar. 22, 2006 (TW) 095109779

(51) Int. Cl. H01L 21/00

(52) U.S. Cl. 438/460

(57) ABSTRACT

A method for dicing a wafer is provided. A layer of adhesive material is applied to the back surface of the wafer so as to provide a sufficient mechanical strength for the wafer during dicing process thereby preventing the dice diced from the wafer from undue chipping on the back surfaces and the side surfaces.

### CROSS REFERENCE TO RELATED APPLICATION

This application claims the priority benefit of Taiwan Patent Application Serial Number 095109779 filed Mar. 22, 2006, the full disclosure of which is incorporated herein by reference.

### BACKGROUND OF THE INVENTION

1. Field of the Invention

The present invention relates to a method for making a semiconductor package, and more particularly, to a method for dicing a wafer.

2. Description of the Related Art

Conventionally, the method for making a semiconductor package is first to cut a wafer into dice and then package these dice into a variety of semiconductor packages. FIGS. 1a and 1b illustrate a conventional method for dicing a wafer. First, as shown in FIG. 1a, a tape 120 is attached to the back surface of a wafer 110 that has been ground and polished to a desired thickness, and then the tape 120 is fixed to a frame (not shown in the figure). Referring to FIG. 1b, a cutter 130 of a dicing machine is then used to dice the wafer 110. After the wafer 110 is diced, the dice diced from the wafer 110 will continue to be kept on the tape 120 until a next process.

The conventional method for dicing a wafer is usually apt to cause the occurrence of 20-micron to 30-micron chippings on the back surfaces and/or side surfaces of the dice. These chippings are acceptable to the dice with the thickness about 10 to 12 mils. However, as electronic devices continue to become lighter and smaller, the thickness of the wafer for these semiconductor devices has been down to 2 to 3 mils. These 20-micron to 30-micron chippings are thus one-third or even one-half of the thickness of the dice. By contrast, these chippings are unacceptable to the dice with the thickness only about 2 to 3 mils.

In order to solve the above-mentioned problems, the Japanese Patent Publication No. 63-37612 discloses a method for dicing a wafer that can prevent the wafer to be diced from chipping during dicing process by printing or attaching an epoxy to the back surface of the wafer. The method for dicing a wafer disclosed in the above-identified invention is to bake a wafer with an epoxy attached to the back surface thereof and then cut the wafer into dice. These dice are baked again to render the epoxy attached to the dice softened. The softened epoxy is adhesive and therefore the dice can be attached to leadframes or substrates by the adhesive epoxy. However, in order to make the epoxy attached to the dice adhesive enough to let the dice easily attach to leadframes or substrates, the epoxy on the back surface of the wafer cannot be baked to fully cure before the wafer is diced. In other words, the epoxy cannot be cured to C-stage before the wafer is diced. The epoxy is at most cured to B-stage before the wafer is diced. As a result, the B-stage epoxy is not strongly attached to the back surface of the wafer and the wafer is still likely to chip during dicing process.

Accordingly, there exists a need to provide a method for dicing a wafer to solve the aforesaid problems.

### SUMMARY OF THE INVENTION

It is an object of the present invention to provide a method for dicing a wafer that can prevent the dice diced from the wafer from undue chipping on the back surfaces and the side surfaces during dicing process.

In order to achieve the above object, the method for dicing a wafer according to the present invention is first to apply a layer of adhesive material to the back surface of the wafer. The layer of adhesive material on the wafer is then to be cured to form a hardened adhesive layer that is not adhesive. Last, the wafer is diced into dice.

To facilitate the dicing of the wafer, a tape is attached to the adhesive layer on the back surface of the wafer and then the tape is fixed to a frame. In order to uniformly form the adhesive layer on the back surface of the wafer, the active surface of the wafer is attached to a turntable. An adhesive material is applied onto the center of the back surface of the wafer during the rotation of the wafer together with the turntable. The adhesive material is uniformly spread over the back surface of the wafer as a result of centrifugal force. The adhesive material is then to be cured to form the hardened adhesive layer.

In the method for dicing a wafer according to the present invention, the adhesive layer formed on the back surface of the wafer provides a sufficient mechanical strength for the wafer during dicing process thereby preventing the dice diced from the wafer from undue chipping on the back surfaces and the side surfaces.

The foregoing, as well as additional objects, features and advantages of the invention will be more readily apparent from the following detailed description, which proceeds with reference to the accompanying drawings.

### BRIEF DESCRIPTION OF THE DRAWINGS

FIGS. 1a and 1b are schematic views illustrating a convention method for dicing a wafer.

FIGS. 2a to 2c are schematic views illustrating the method for dicing a wafer according to the present invention.

FIG. 3 is a schematic view illustrating the method for uniformly forming the adhesive layer on the back surface of the wafer in FIG. 2a.

FIGS. 4a and 4b are the enlarged pictures of the dice that are diced from wafers in the conventional methods.

FIG. 4c is the enlarged picture of the die that is diced from a wafer in the method of the present invention.

### DETAILED DESCRIPTION OF THE PREFERRED EMBODIMENT

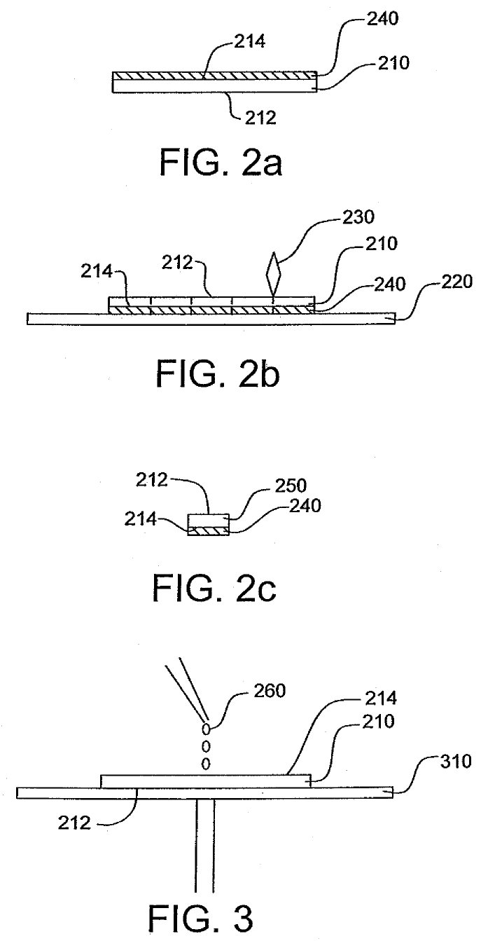

FIGS. 2a to 2c illustrate the method for dicing a wafer according to the present invention. Referring to FIG. 2a, after a wafer 210 has been ground and polished to a desired thickness, a layer of adhesive material which is adhesive is applied to the back surface 214 of the wafer 210. The layer of adhesive material on the wafer 210 is then to be cured by baking or UV illumination to form a hardened adhesive layer 240 that is not adhesive. Preferably, the adhesive layer 240 is made of a non-conductive and thermosetting material. Referring to FIG. 2b, a tape 220 is attached to the hardened adhesive layer 240, and then the tape 220 is fixed to a frame (not shown in the figure) to hold the wafer 210 with its active surface 212 faced up. The wafer 210 is diced from its active surface 212 by a cutter 230 into a plurality of dice 250 (see FIG. 2c).

In the method for dicing a wafer according to the present invention, the hardened adhesive layer 240 attached to the back surface 214 of the wafer 210 can provide a sufficient mechanical strength for the wafer 210 during dicing process so as to prevent the dice 250 diced from the wafer 210 from undue chipping on the back surfaces 214 and side surfaces. The die 250 with the adhesive layer 240 thereon can be mounted directly onto a leadframe or substrate without removing the adhesive layer 240 in advance. Additionally, the adhesive layer 240 can also provide an additional isolation protection to the die 250 as the adhesive layer 240 is made of a non-conductive material.

Referring to FIG. 3, in order to uniformly form the adhesive layer 240 on the back surface 214 of the wafer 210, the active surface 212 of the wafer 210 is attached to a turntable 310. The wafer 210 is driven to rotate by the turntable 310 and an adhesive material 260 is applied onto the center of the back surface 214 of the wafer 210 during rotation. The adhesive material 260 is uniformly spread over the back surface 214 of the wafer 210 as a result of centrifugal force. The adhesive material 260 is then to be cured to form the hardened adhesive layer 240.

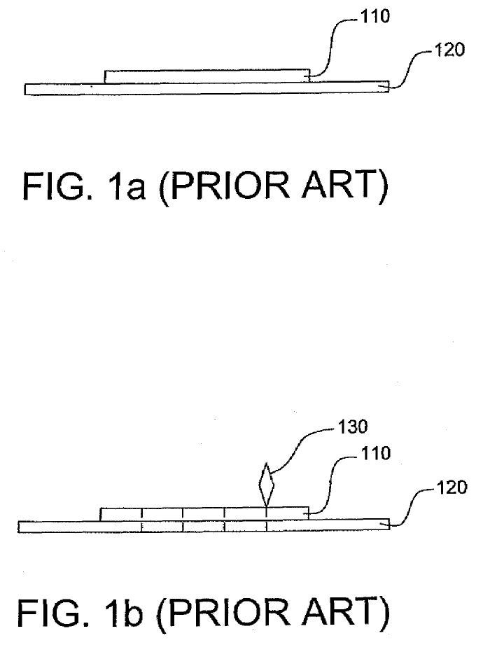

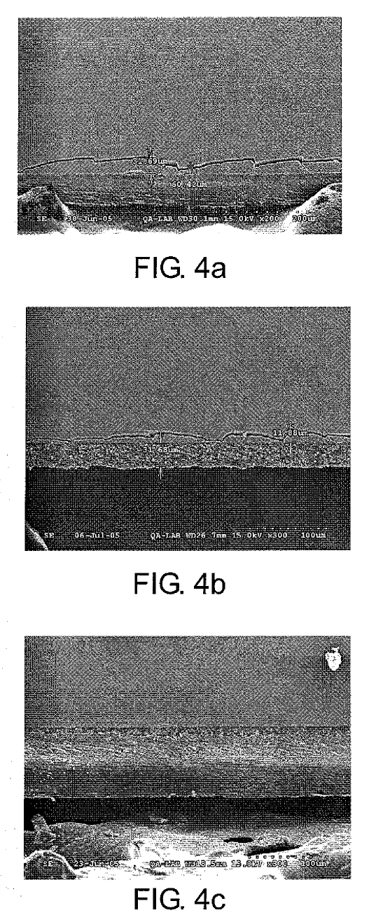

Referring to FIGS. 4a to 4c, they illustrate the enlarged pictures of the dice that are diced from wafers in the above-mentioned conventional methods and in the method of the present invention respectively. As shown in the FIG. 4a, the die diced from a wafer directly attached to a tape as illustrated in FIGS. 1a to 1b shows clear chipping on the side surface near the back surface. Chipping is also similarly shown on the side surface of the die (see FIG. 4b) diced from a wafer that is first attached a B-stage adhesive layer and then to be attached to a tape as disclosed in the Japanese Patent Publication No. 63-37612. By contrast, referring to FIG. 4c, the die diced from a wafer in the method for dicing a wafer according to the present invention dose not present chipping on the side surface.

Although the preferred embodiments of the invention have been disclosed for illustrative purposes, those skilled in the art will appreciate that various modifications, additions and substitutions are possible, without departing from the scope and spirit of the invention as disclosed in the accompanying claims.

What is claimed is:

1. A method for dicing a wafer, comprising:
providing a wafer having opposing active and back surfaces;
applying a layer of adhesive material to the back surface of the wafer;
curing the layer of adhesive material to form a hardened adhesive layer on the back surface of the wafer; and
dicing the wafer into a plurality of dice.

2. The method as claimed in claim 1, further comprising:
attaching a tape to the hardened adhesive layer on the back surface of the wafer.

3. The method as claimed in claim 1, wherein the step of applying a layer of adhesive material to the back surface of the wafer comprises:
attaching the active surface of the wafer to a turntable;
rotating the turntable to drive the wafer to rotate; and
applying the adhesive material onto the center of the back surface of the wafer to make the adhesive material uniformly spread over the back surface of the wafer.

4. The method as claimed in claim 1, wherein the adhesive layer is non-conductive.

5. The method as claimed in claim 1, wherein the wafer is diced from the active surface of the wafer.

6. The method as claimed in claim 1, wherein the adhesive material is adhesive before curing.

7. The method as claimed in claim 6, wherein the hardened adhesive layer is not adhesive.

8. The method as claimed in claim 1, wherein the adhesive material is thermosetting.

9. The method as claimed in claim 1, wherein the layer of adhesive material is cured by baking.

10. The method as claimed in claim 1, wherein the layer of adhesive material is cured by UV illumination.

11. A method for dicing a wafer, comprising:
providing a wafer having opposing active and back surfaces;
attaching the active surface of the wafer to a turntable;
rotating the turntable to drive the wafer to rotate;
applying an adhesive material onto the center of the back surface of the wafer to make the adhesive material uniformly spread over the back surface of the wafer; curing the adhesive material to form a hardened adhesive layer on the back surface of the wafer;
attaching a tape to the hardened adhesive layer on the back surface of the wafer; and
dicing the wafer into a plurality of dice.

12. The method as claimed in claim 11, wherein the hardened adhesive layer is non-conductive.

13. The method as claimed in claim 11, wherein the wafer is diced from the active surface of the wafer.

14. The method as claimed in claim 11, wherein the adhesive material is adhesive before curing.

15. The method as claimed in claim 14, wherein the hardened adhesive layer is not adhesive.

16. The method as claimed in claim 11, wherein the adhesive material is thermosetting.

17. The method as claimed in claim 11, wherein the adhesive material is cured by baking.

18. The method as claimed in claim 11, wherein the adhesive material is cured by UV illumination.
